(19) United States
(12) Patent Application Publication
(10) Pub. No.: US 2007/0032104 A1
(43) Pub. Date: Feb. 8, 2007

(54) Electrical connector

(75) Inventors: Akio Yamada, Tokyo (JP); Kazuyuki Ozai, Tokyo (JP); Shinya Ishizuka, Tokyo (JP)

Correspondence Address: ABELMAN, FRAYNE & SCHWAB, 666 THIRD AVENUE, 10TH FLOOR, NEW YORK, NY, 10017, US

(73) Assignee: DDK LTD.

(21) Appl. No.: 11/501,988

(22) Filed: Aug. 9, 2006

(30) Foreign Application Priority Data
Aug. 8, 2005 (JP) 2005-228,975

(51) Int. Cl. H05K 1/00

(52) U.S. Cl. 439/76.1

(57) ABSTRACT

An electrical connector includes, in substitution for contacts, a substrate having a plurality of signal patterns and a plurality of ground patterns on at least one surface, each of these patterns having at one end a contact portion adapted to contact a mating object and at the other end a connection portion to be connected to a cable, a housing having an inserting hole for inserting the substrate therethrough, and holding members for fixing the substrate to the housing. A capacitor and a resistance chip connected in parallel are mounted on at least one of the signal patterns. In this manner, the connector achieves its miniaturization, stability of impedance, reduction in cross talk, and better return loss level and transmission characteristics.

### BACKGROUND OF THE INVENTION

The present invention relates to an electrical connector for use in electric and electronic appliances such as servers, super computers and the like, and more particularly to a connector which achieves reduction in cross talk when connected to cables and improvement in reflective attenuation or transmission characteristics.

In recent years, with miniaturization of electronic and electric appliances, there has been an increasing demand for miniaturization of electrical connectors. Most of electrical connectors (not shown) each comprise an insulator formed of an electrically insulating material and contacts formed of a conductive material. The contacts each comprise a contact portion adapted to contact a mating object, a fixed portion to be fixed to the insulator, and a connection portion to be connected to a substrate or a cable. The contacts may be fixed to the insulator by means of press-fitting, hooking (lancing) or the like.

On proceeding of narrower pitches of contacts, flexible printed circuit boards (FPC) or substrate patterns have been used as contact portions and connection portions instead of the contacts as in the following Patent Literature 1.

Moreover, there has been a proposal in which a rigid substrate and a flexible substrate are directly connected to each other as disclosed in the following Patent Literature 2.

Patent Literature 1

An example of the use of a substrate or the like as contact portions and connection portions in substitution for contacts is disclosed in Japanese Patent Application Opened No. H10-32,062 (1998). According to the ABSTRACT of this prior art, the Japanese Patent application Opened No. H10-32,062 has an object to provide an electrical connector which is mounted on a substrate and able to be connected to a mating connector mounted on a substrate irrespective of positional deviation (of the order of 0.5 mm) between the substrates. This object can be achieved by providing means for holding and fixing contacts in an insulator and providing a flexibility to the contacts. Disclosed are contacts each comprising two contact members attached to each other and each of the contact members consisting of a conductor and insulating layers A and B embracing the conductor therebetween. In other words, flexible printed circuit boards are used as the contact members to enhance the floating of the connector when being fitted with the mating connector.

Patent Literature 2

According to the ABSTRACT of the Japanese Patent Application Opened No. H7-15,106 (1995), the prior art has an object to prevent deterioration of electrical characteristics such as signal deterioration and the like when a rigid substrate and a flexible substrate are directly connected to each other. Disclosed is a configuration in that in a contact pattern consisting of narrow patterns for directly connecting a rigid substrate and a flexible substrate, ground patterns are arranged at a rate of one ground pattern per n signal patterns to make impedance of the contact pattern stable, to prevent the influence of noise and static electricity, to reduce deterioration in signals due to cross talk noise between signal patterns, and to prevent deterioration in electrical characteristics. In other words, signal patterns and ground patterns are arranged to locate n signal patterns between ground patterns, thereby achieving the stability of impedance.

In recent years, with miniaturization of electronic and electric appliances, there has been an increasing demand for miniaturization of connectors, and in response thereto the connectors have become progressively lighter and more compact. On the other hand, on proceeding of high speed transmission (speeding up of signal speed), the reduction in cross talk has become absolutely imperative.

With the electrical connector disclosed in the Patent Literature 1, the flexible printed circuit boards are used to enhance the floating when the connector is being fitted. The connection portions are of a surface mounting type (SMT) and are not to be connected to cables. With this electrical connector, the contacts are not distinguished as signal contacts and ground contacts. Moreover, this electrical connector is neither making the impedance stable nor reducing the cross talk.

The construction disclosed in the Patent Literature 2 includes the ground patterns arranged at a rate of one ground pattern per n signal patterns to intend to make stable the impedance of the contact patterns, but does not achieve reduction in cross talk.

In addition, improvement in return loss level and transmission characteristics is frequently required other than the reduction in cross talk depending upon customers demands.

### SUMMARY OF THE INVENTION

With the view to such problems of the prior art, it is an object of the invention to provide an electrical connector having benefits including miniaturized connector, stability of impedance, reduction in cross talk, and improvement in return loss level and transmission characteristics.

The object described above can be achieved by the electrical connector 10 including a plurality of contacts and a housing 12 for arranging and holding the contacts therein, wherein according to the invention the electrical connector 10 comprises in substitution for the contacts, a substrate 14 including a plurality of signal patterns 20 and a plurality of ground patterns 22 provided on at least one surface, each of these patterns 20, 22 having at one end a contact portion 28 adapted to contact a mating article and at the other end a connection portion 30 to be connected to a cable 16; the housing 12 having an inserting hole 34 for inserting the substrate 14 therethrough; and holding means for fixing the substrate 14 to the housing 12, and a capacitor 38 and a resistance chip 40 connected in parallel are mounted on at least one of the signal patterns 20.

In a preferred embodiment of the invention, the holding means comprises at least two anchoring portions 32 provided at predetermined positions of the substrate 14, and holding members 18 each having a substantially U-shape and having engaging portions 42 adapted to engage the anchoring portion 32 so that the holding members 18 are inserted into inserting slits 36 of the housing 12 to bring the engaging portions 42 into engagement with the anchoring portions 32, respectively.

Moreover, a plurality of the signal patterns 20 and a plurality of the ground patterns 22 are arranged in a manner that one signal pattern 20 is located between two ground patterns 22, and these patterns 20, 22 are arranged on both surfaces of the substrate 14.

Further, the capacitor 38 and the resistance chip 40 connected in parallel are mounted on each of the eight signal patterns 20, and among them the four signal patterns 20 having the capacitor 38 and the resistance chip 40 are mounted on one surface of the substrate 14 and the remaining four signal patterns 20 are mounted on the other surface of the substrate 14 in a symmetrical relationship with the four signal patterns mounted on the one surface of the substrate 14.

As can be seen from the above description, the electrical connector 10 according to the invention can bring about the following significant effects. (1) In an electrical connector 10 including a plurality of contacts and a housing 12 for arranging and holding the contacts therein, according to the invention the electrical connector 10 comprises in substitution for the contacts, a substrate 14 including a plurality of signal patterns 20 and a plurality of ground patterns 22 provided on at least one surface, each of these patterns 20, 22 having at one end a contact portion 28 adapted to contact a mating object and at the other end a connection portion 30 to be connected to a cable 16; the housing 12 having an inserting hole 34 for inserting the substrate 14 therethrough; and holding means for fixing the substrate 14 to the housing 12, and a capacitor 38 and a resistance chip 40 connected in parallel are mounted on at least one of the signal patterns 20. Therefore, the electrical connector according to the invention achieves its miniaturization, superior in stability of impedance, reduction in cross talk, and improvement in return loss level and transmission characteristics.

(2) According to the invention, the holding means comprises at least two anchoring portions 32 provided at predetermined positions of the substrate 14, and holding members 18 each having a substantially U-shape and having engaging portions 42 adapted to engage the anchoring portion 32 so that the holding members 18 are inserted into inserting slits 36 of the housing 12 to bring the engaging portions 42 into engagement with the anchoring portions 32, respectively. Consequently, the electrical connector according to the invention ensures reliable arrangement to support the substrate 14 in the housing 12, thereby enabling stable electrical connection.

(3) According to the invention, a plurality of the signal patterns 20 and a plurality of the ground patterns 22 are arranged in a manner that one signal pattern 20 is located between two ground patterns 22, and these patterns 20, 22 are arranged on both surfaces of the substrate 14. Therefore, the connector according to the invention achieves the reduction in cross talk.

(4) According to the invention, the capacitor 38 and the resistance chip 40 connected in parallel are mounted on each of the eight signal patterns 20, and among them the four signal patterns 20 having the capacitor 38 and the resistance chip 40 are mounted on one surface of the substrate 14 and the remaining four signal patterns 20 are mounted on the other surface of the substrate 14 in a symmetrical relationship with the four signal patterns mounted on the one surface of the substrate 14. Consequently, the electrical connector according to the invention achieves its miniaturization, superiority in stability of impedance, reduction in cross talk, and improvement in return loss level and transmission characteristics.

The invention will be more fully understood by referring to the following detailed specification and claims taken in connection with the appended drawings.

### BRIEF DESCRIPTION OF THE DRAWINGS

FIG. 1A is a perspective view of an electrical connector according to the invention viewed from the fitting side;

FIG. 1B is a perspective view of the electrical connector according to the invention viewed from the connection portion side;

FIG. 2A is an exploded perspective view of parts of the electrical connector viewed from the connection portion side;

FIG. 2B is an exploded perspective view of the parts of the electrical connector viewed from the fitting side;

FIG. 3A is a perspective view of a substrate viewed from the fitting side;

FIG. 3B is a perspective view of the substrate viewed from the connection portion side;

FIG. 4 is a perspective view of a holding member;

FIG. 5A is a perspective view of a housing viewed from the fitting side; and

FIG. 5B is a perspective view of the housing viewed from the connection portion side.

### DESCRIPTION OF THE PREFERRED EMBODIMENTS

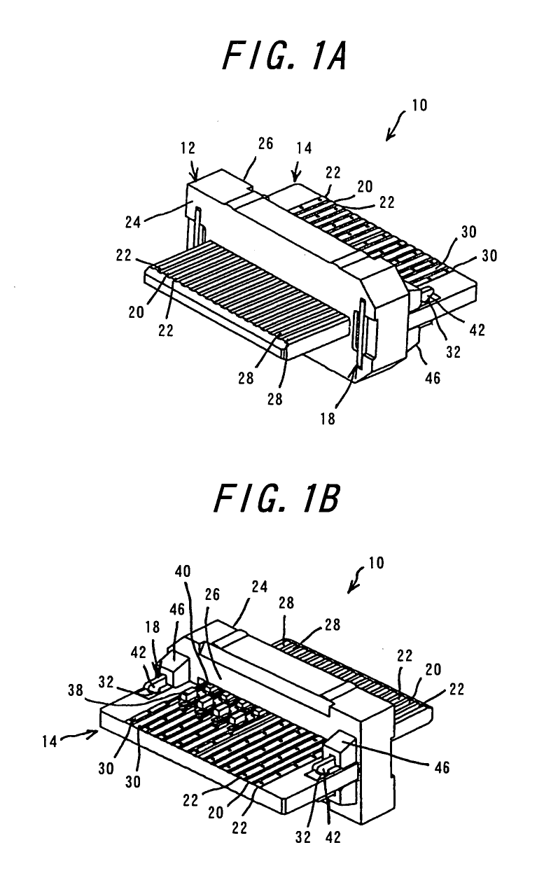

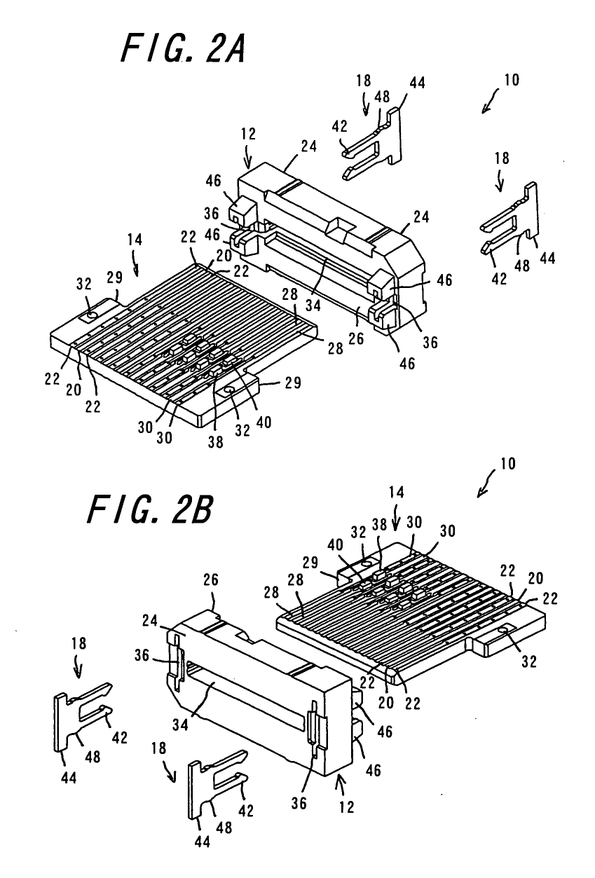

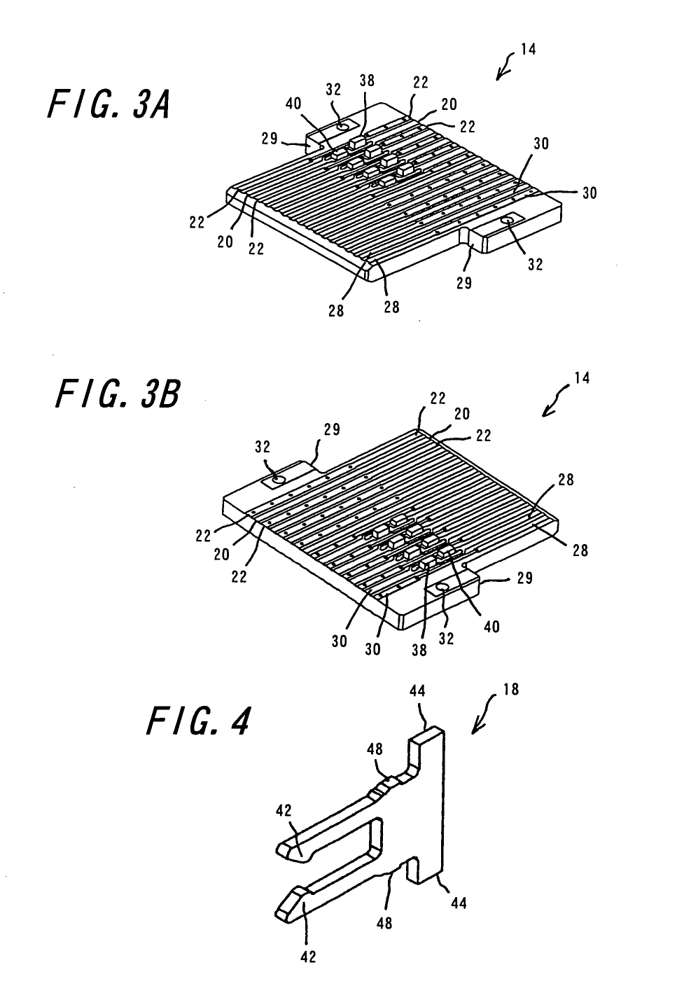

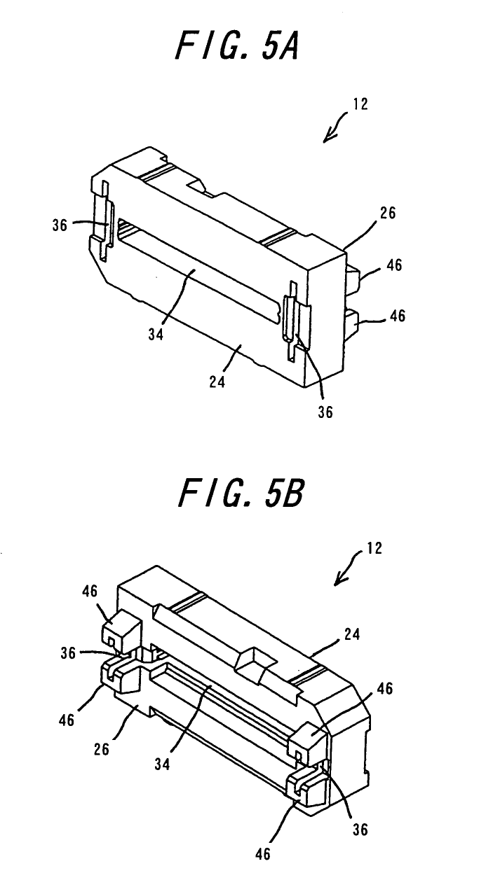

One embodiment of the electrical connector 10 according to the invention will be explained with reference to FIGS. 1A to 5B. FIG. 1A is a perspective view of the electrical connector according to the invention viewed from the fitting side, and FIG. 1B is a perspective view of the electrical connector according to the invention viewed from the connection portion side. FIG. 2A is an exploded perspective view of parts of the electrical connector viewed from the connection portion side, while FIG. 2B is an exploded perspective view of the parts of the electrical connector viewed from the fitting side. FIG. 3A is a perspective view of a substrate with capacitors and resistance chips mounted thereon viewed from the fitting side, and FIG. 3B is a perspective view of the substrate with the capacitors and resistance chips mounted thereon viewed from the connection portion side. FIG. 4 is a perspective view of a holding member. FIG. 5A is a perspective view of a housing viewed from the fitting side, while FIG. 5B is a perspective view of the housing viewed from the connection portion side.

The electrical connector 10 according to the one embodiment of the invention mainly comprises a housing 12, a substrate 14 and holding members 18. This electrical connector 10 uses the substrate 14, instead of providing contacts. The substrate 14 is adapted to contact a mating object to achieve a narrower pitch of conductors and a miniaturization of the connector 10.

First, the substrate 14 will be explained, which is one subject matter of the invention. In electrical connectors, in general, contacts are used to exchange signals. According to the invention, however, the substrate 14 is used instead of the contacts. The substrate 14 mainly comprises signal patterns 20 and grand patterns 22, each of these patterns having a contact portion 28 adapted to contact a mating object and a connection portion 30 adapted to be connected to a cable or the like. As shown in FIGS. 3A and 3B, the substrate 14 is substantially T-shaped having shoulders 29 one on each side of its one end for positioning the substrate 14 relative to the housing 12 when the former is inserted into the latter. The signal patterns 20 and the grand patterns 22 are arranged in a manner that one signal pattern 20 is located between two ground patterns 22. The signal patterns 20 are arranged between the ground patterns 22 to provide shielding effect, thereby obtaining a stability of impedance. The signal patterns 20 and the ground patterns 22 may be arranged on both the surfaces of the substrate 14 as in the illustrated embodiment. However, they may be arranged only on either one of the surfaces of the substrate 14 depending upon customer's specifications.

The size of the substrate 14 may be suitably designed in consideration of requested specifications and condition of miniaturization, strength and the like of the connector. As the pitch of the signal patterns 20 is 1.5 mm in the illustrated embodiment, the substrate 14 is 16.8 mm in the lengthwise direction, 14 mm in the traverse direction and 1.2 mm in thickness. As shown in FIGS. 3A and 3B, the substrate 14 is provided at both the lengthwise ends with anchoring portions 32 adapted to engage engaging portions 42 of the holding members 18, respectively. The shape of the anchoring portions 32 may be any one insofar as they can engage the engaging portions 42 of the holding members 18. The anchoring portions 32 are through-holes in the embodiment shown in FIGS. 3A and 3B, or may be U-shaped notches (not shown), or may be blind holes according to specifications.

A capacitor 38 and a resistance chip 40 are connected in parallel and mounted on at least one signal pattern 20 on the substrate 14. The capacitor 38 and the resistance chip 40 are connected in parallel and mounted on the signal pattern 20 to intend to improve return loss level and transmission characteristics. In the illustrated embodiment, four signal patterns 20 each having the capacitor 38 and the resistance chip 40 connected in parallel are provided on each of the surfaces of the substrate 14 so that the four signal patterns 20 on one surface of the substrate are in a symmetrical relationship to the four signal patterns 20 on the other surface of the substrate, i.e. amount to a total of eight signal patterns 20 having the capacitor 38 and the resistance chip 40. The substrate 14 with the capacitors 38 and the resistance chips 40 mounted thereon is inserted into the housing 12.

The housing 12 will then be explained. The housing 12 is formed from an electrically insulating plastic material by means of the injection molding of the known technique. The material for the housing 12 may be suitably selected in consideration of dimensional stability, workability, manufacturing cost and the like. In general, suitable materials for the housing 12 include polybutylene terephthalate (PBT), polyamide (66PA or 46PA), liquid crystal polymer (LCP), polycarbonate (PC) and the like and combination thereof.

As shown in FIGS. 5A and 5B, the housing 12 is provided with an inserting hole 34 for inserting the substrate 14 therethrough. The substrate 14 is fixed to the housing 12 by press-fitting, hooking (lancing) including the case of using separate parts, and the like. The method for fixing the substrate to the housing may be determined in consideration of strength of the substrate, positional accuracy, holding force and the like. However, the hooking using separate parts is the most preferable. In the illustrated embodiment, the holding members 18 as described below are inserted into the housing 12 from the fitting side 24 so that parts of the holding members 18 are hooked in the anchoring portions 32 of the substrate 14 to fix the substrate 14 to the housing 12.

Moreover, the housing 12 is provided at each of the longitudinal ends with two protrusions 46 spaced a predetermined distance apart from each other and opposed to each other in the direction of the thickness of the substrate 14 inserted in the housing 12, i.e. with a total of four protrusions 46. The shoulders 29 of the substrate 14 are inserted between the protrusions 46 or into the spaces of the predetermined distance. The distance between the opposed protrusions 46 may be suitably designed in consideration of the thickness of the substrate 14, and is a distance which is approximately 0.2 mm larger than the thickness of the substrate 14 in the illustrated embodiment. In order to position the substrate 14 in its lengthwise direction relative to the housing 12, a required number of crushed ribs (not shown) are provided in the inserting hole 34 at its longitudinal ends. In the illustrated embodiment, considering such a function there are provided two crushed ribs at each of the longitudinal ends, i.e. with a total of four crushed ribs.

Concerning the size of the inserting hole 34 in connection with the above description, its longitudinal dimension may be designed in consideration of deviations in pitches of the patterns 20 and 22. In the illustrated embodiment, the crushed ribs are provided as described above, and the substrate 14 is press-fitted into the inserting hole 34 without particularly positioning the substrate 14 in its thickness direction. Accordingly, the inserting hole 34 in the direction of the thickness of the substrate 14 is approximately 0.2 mm larger than the thickness of the substrate 14. The positioning of the substrate 14 is carried out by the holding members 18 as described below.

Further, the housing 12 is formed at each of the longitudinal ends with an inserting slit 36 passing through the housing 12 from the fitting side 24 to the connection portion side 26 over the opposed protrusions 46 for fixing the holding members 18 therein. The size of the inserting slits 36 may be designed in consideration of holding force of the holding members 18 for the substrate 14, strength of the housing 12 and the like, and is 2.98 mm×0.45 mm in the illustrated embodiment.

The holding members 18 will then be explained. The holding members 18 are made of a metal and formed by means of the press-working of the known technique. Preferred metals from which to form the holding members 18 include brass, beryllium copper, phosphor bronze and the like which comply with the requirements such as dimensional stability, workability and the like.

The holding members 18 are inserted into the inserting slits 36 of the housing 12 from the fitting side 34 and fixed therein by means of press-fitting. The holding member 18 is substantially U-shaped as shown in FIG. 4 and comprises the engaging portions 42 adapted to engage the anchoring portions 32 of the substrate 14, respectively, fixed portions 48 for press-fitting the holding member 18 into the housing 12, and positioning portions 44 for positioning the holding member 18 and increasing the holding force of the holding member 18.

The shape of the engaging portions 42 may be designed in consideration of the holding force for the substrate 14 and engaging ability and may be any one so long as these requirements are fulfiled. The engaging portions are rounded triangular projections inwardly extending to each other in the illustrated embodiment. The size of the fixed portions 48 may be determined so as to be inserted into and fixed to the inserting slits 36 of the housing 12. The positioning portions 44 serve to control the inserted depth in the housing 12 upon inserting the holding member 18 into the inserting slit 36 of the housing 12, and to prevent the substrate 14 from being removed from the housing 12 onto the connection portion side 26 when cables connected to the substrate 14 are accidentally subjected to external forces. The size of the positioning portions 44 may be suitably designed in consideration of these functions and the strength of the housing 12.

As described above, since the substrate 14 is positioned in the direction of its thickness by means of the holding members 18, the distance between the arms forming a U-shape except for the inwardly extending engaging portions 42 of the holding member 18 as shown in FIG. 4 is substantially the same as the thickness of the substrate 14.

Finally, sequence of assembling the electrical connector 10 will be explained. First, the substrate 14 with a required number of the capacitors 38 and the resistance chips 40 mounted thereon is inserted into the inserting hole 34 of the housing 12 from the connection portion side 26.

Subsequently, the holding members 18 are inserted into the inserting slits 36 of the housing 12 from the fitting side 24, respectively, so that the engaging portions 42 of the holding members 18 are caused to be engaged into the anchoring portions 32 of the substrate 14, respectively.

Finally, cables 16 are connected to the predetermined connection portions 30 of the substrate 14. If necessary, the connector 10 according to the invention may be enclosed by upper and lower covers or the like.

Examples of practical use of the connector according to the invention are electrical connectors for use in electric and electronic appliances such as servers, super computers and the like, and particularly electrical connectors which achieve reduction in cross talk when connected to cables and improvement in return loss level and transmission characteristics.

While the invention has been particularly shown and described with reference to the preferred embodiments thereof, it will be understood by those skilled in the art that the foregoing and other changes in form and details can be made therein without departing from the spirit and scope of the invention.

What is claimed is:

1. An electrical connector including a plurality of contacts and a housing for arranging and holding said contacts therein, said electrical connector comprising in substitution for said contacts, a substrate including a plurality of signal patterns and a plurality of ground patterns provided on at least one surface, each of these patterns having at one end a contact portion adapted to contact a mating object and at the other end a connection portion to be connected to a cable; said housing having an inserting hole for inserting said substrate therethrough; and holding means for fixing said substrate to the housing, and a capacitor and a resistance chip connected in parallel being mounted on at least one of said signal patterns.

2. The electrical connector as set forth in claim 1, wherein said holding means comprises at least two anchoring portions provided at predetermined positions of said substrate, and holding members each having a substantially U-shape and having engaging portions adapted to engage said anchoring portion so that said holding members are inserted into inserting slits of the housing to bring the engaging portions into engagement with said anchoring portions, respectively.

3. The electrical connector as set forth in claim 1, wherein the plurality of said signal patterns and the plurality of said ground patterns are arranged in a manner that one signal pattern is located between two ground patterns, and these patterns are arranged on both surfaces of said substrate.

4. The electrical connector as set forth in claim 1, wherein the capacitor and the resistance chip connected in parallel are mounted on each of the eight signal patterns, and among them the four signal patterns having the capacitor and the resistance chip are mounted on one surface of said substrate and the remaining four signal patterns are mounted on the other surface of said substrate in a symmetrical relationship with said four signal patterns mounted on the one surface of said substrate.

5. The electrical connector as set forth in claim 2, wherein the plurality of said signal patterns and the plurality of said ground patterns are arranged in a manner that one signal pattern is located between two ground patterns, and these patterns are arranged on both surfaces of said substrate.

6. The electrical connector as set forth in claim 2, wherein the capacitor and the resistance chip connected in parallel are mounted on each of the eight signal patterns, and among them the four signal patterns having the capacitor and the resistance chip are mounted on one surface of said substrate and the remaining four signal patterns are mounted on the other surface of said substrate in a symmetrical relationship with said four signal patterns mounted on the one surface of said substrate.

7. The electrical connector as set forth in claim 3, wherein the capacitor and the resistance chip connected in parallel are mounted on each of the eight signal patterns, and among them the four signal patterns having the capacitor and the resistance chip are mounted on one surface of said substrate and the remaining four signal patterns are mounted on the other surface of said substrate in a symmetrical relationship with said four signal patterns mounted on the one surface of said substrate.

8. The electrical connector as set forth in claim 5, wherein the capacitor and the resistance chip connected in parallel are mounted on each of the eight signal patterns, and among them the four signal patterns having the capacitor and the resistance chip are mounted on one surface of said substrate and the remaining four signal patterns are mounted on the other surface of said substrate in a symmetrical relationship with said four signal patterns mounted on the one surface of said substrate.
